(19) United States
(12) Patent Application Publication
(10) Pub. No.: US 2022/0113946 A1
(43) Pub. Date: Apr. 14, 2022

(54) APPARATUS FOR GENERATING RANDOM DATA AND A METHOD THEREOF

(71) Applicant: SILICONCH SYSTEMS PVT LTD, Karnataka (IN)

(72) Inventors: Jaswanth AMMINENI, Karnataka (IN); Abhishek Dattatraya SARDESHPANDE, Karnataka (IN); Rakesh Kumar POLASA, Karnataka (IN)

(73) Assignee: SILICONCH SYSTEMS PVT LTD

(21) Appl. No.: 17/149,554

(22) Filed: Jan. 14, 2021

(30) Foreign Application Priority Data
Oct. 13, 2020 (IN) 202041044567

(51) Int. Cl. G06F 7/58; H03K 19/21

(52) U.S. Cl. CPC G06F 7/582; H03K 19/215

(57) ABSTRACT

The present disclosure pertains to a circuitry for generating random data. The random data can be numbers. The circuitry includes a ring oscillator, a metastable oscillator, a first circuitry, and an analogue circuitry. The ring oscillator has a ring oscillator output frequency selectable through a selectable input of the ring oscillator. The metastable oscillator has a metastable oscillator output frequency selectable through a selectable input of the metastable oscillator. The first circuitry has a ring oscillator chain size selection logic circuit. The analogue circuitry has a capacitor and a switch used for varying frequency of the ring oscillator. The switch is configured to be controlled by the selection logic circuit of the first circuitry.

### CROSS REFERENCE TO RELATED APPLICATIONS

This Paris Convention Patent application claims benefit under 35 U.S.C. § 119 and claims priority to Indian Patent Application No. IN 202041044567, filed on Oct. 13, 2020, titled “AN APPARATUS FOR GENERATING RANDOM DATA AND A METHOD THEREOF”, the content of which is incorporated herein in its entirety by reference for all purposes.

### TECHNICAL FIELD

The present disclosure generally relates to random number generators. More particularly, the present disclosure relates to a true random number generator with secure and improved entropy between generated sequence.

### BACKGROUND

Background description includes information that can be useful in understanding the present invention. It is not an admission that any of the information provided herein is prior art or relevant to the presently claimed invention, or that any publication specifically or implicitly referenced is prior art.

A random number generator (abbreviated as RNG) is a computational or physical device designed to generate a sequence of numbers or symbols that lack any pattern, i.e., appear random. Computer-based systems for random number generation are widely used, but often fall short of this goal, though they may meet some statistical tests for randomness intended to ensure that they do not have any easily discernible patterns. Methods for generating random results have existed since ancient times, including dice, coin flipping, the shuffling of playing cards, the use of yarrow stalks in the I Ching, and many other techniques.

A hardware random number generator (abbreviated as HRNG) or true random number generator (TRNG) is a device that generates random numbers from a physical process, rather than by means of an algorithm. Such devices are often based on microscopic phenomena that generate low-level, statistically random “noise” signals, such as thermal noise, the photoelectric effect, involving a beam splitter, and other quantum phenomena. These stochastic processes are, in theory, completely unpredictable, and the theory's assertions of unpredictability are subject to experimental test. This is in contrast to the paradigm of pseudo-random number generation commonly implemented in computer programs.

Another important characteristic associated with TRNGs is a state of entropy associated with the randomness aspect of the numbers. In simple terms, entropy in a TRNG context can be said to refer to a lack of predictability as to the randomness aspect of the numbers. Thus, there is a need for a TRNG that has a lack of predictability associated with it.

In order to ensure the uniqueness of the random number sequence, the random number sequence generated by the random number generator may include random numbers exceeding the pre-set number, and the length of the machine random number sequence can be long. However, not all cases require a random number sequence whose length exceeds a pre-set value, and the length of the random number sequence is too long, and the random number sequence occupies a large space, which wastes computer memory for the computer. Therefore, it is necessary to generate a random number sequence having a reduced length of the random number sequence while maintaining the uniqueness of the random number sequence.

In particular, a True Random Number Generator (TRNG) block is used for generating raw random bits with high amount of uncorrelation in successive and collective data stream. A TRNG block can include two channels: a) Ring Oscillator (RO TRNG); or a b) Metastability (META TRNG). The data stream generated by RO TRNG is sampled in a digital domain whereas the sampling flop for data generated by META TRNG is sampled in an analogue domain.

Attempts have been made in to provide an improved TRNG. However, a need in the art still exists to provide a reliable and efficient true random number generator with secure and improved entropy between generated sequence.

### OBJECTS OF THE INVENTION

It is an object of the present invention to provide a true random number generator with secure and improved entropy between generated sequence.

It is another object of the present invention to provide a simple and cost effective true random number generator with secure and improved entropy between generated sequence.

It is another object of the present invention to provide a reliable and efficient true random number generator with secure and improved entropy between generated sequence.

It is another object of the present invention to provide a robust true random number generator with secure and improved entropy between generated sequence.

It is another object of the present invention to provide a secure storage mechanism for the robust true random number generator with secure and improved uncorrelation between the generated sequences.

### SUMMARY

The present disclosure generally relates to random number generators. More particularly, the present disclosure relates to a true random number generator with secure and improved entropy between generated sequence.

An aspect of the present disclosure pertains to an apparatus for generating random data. The random data can be numbers. The apparatus includes a ring oscillator, a metastable oscillator, a first circuitry, and an analogue circuitry. The ring oscillator has a ring oscillator output frequency selectable through a selectable input of the ring oscillator. The metastable oscillator has a metastable oscillator output frequency selectable through a selectable input of the metastable oscillator. The first circuitry has a ring oscillator (RO) chain size selection logic circuit. The analogue circuitry has a capacitor and a switch used for varying frequency of the ring oscillator. The switch is configured to be controlled by the selection logic circuit of the first circuitry.

In an aspect, the analogue circuitry is configured to vary the output frequency of the ring oscillator.

In an aspect, the RO chain size selection logic circuit is configured to generate random data based on the output frequency of the ring oscillator and the metastable oscillator.

In an aspect, the generated random data are encoded and scrambled before storage in a storage area.

In another embodiment, the apparatus further includes two or more ring oscillators, each of the ring oscillators configured to operate in tandem with the metastable oscillator, and the first circuitry to generate random data.

In another embodiment, the metastable oscillator further includes a plurality of multiplexers, and a plurality of inverters, the inverters being configured to define a size of the metastable oscillator.

In another embodiment, the chain size selection logic circuit is configured to control the size of the metastable oscillator.

In another embodiment, the chain size selection logic circuit comprises four output signals, which are randomly selected from a 256-bit random data type stored in a storage element.

In another embodiment, the randomly selected output of the chain selection logic is generated using a one-time programmable (OTP) memory block, and an XOR logic circuit.

In another embodiment, the four output signals of the RO chain size selection logic circuit is generated through an interaction of the XOR logic circuit on at least four bytes of 256-bits of the generated random data.

In another embodiment, the at least four random data are selected using the XOR logic circuit.

In another embodiment, the apparatus further comprises a plurality of resistors connected in series with the drain of associated Metal Oxide Silicon Field Effect Transistors (MOSFETS).

Another aspect of the present disclosure pertains to a method for generating random data. The method includes the steps of: selecting an output frequency of a ring oscillator, the output frequency selectable through a selectable input of the ring oscillator; selecting an output frequency of a metastable oscillator, the output frequency selectable through a selectable input of the metastable oscillator; varying the output frequency of the ring oscillator by a switch associated with an analogue circuitry; and generating random data at a communication circuit based on the output frequencies of the ring oscillator and the metastable oscillator.

In an embodiment, the switch varies the output frequency by a chain size selection logic.

In another embodiment, the method further includes the steps of: selecting the output frequencies through respective selectable inputs of the two of more ring oscillators; varying the output frequencies of the two or more ring oscillators by the switch associated with the analogue circuitry; and generating random data by an XOR combination of output frequencies of the two or more ring oscillators.

Various objects, features, aspects, and advantages of the inventive subject matter will become more apparent from the following detailed description of preferred embodiments, along with the accompanying drawing figures in which like numerals represent like components

### BRIEF DESCRIPTION OF THE DRAWINGS

The diagrams are for illustration only, which thus is not a limitation of the present disclosure, and wherein:

FIG. 1 illustrates an exemplary representation of an apparatus for generating random data, in accordance with an embodiment of the present disclosure.

FIG. 2 illustrates an exemplary ring oscillator true random number generator (RO TRNG), in accordance with an embodiment of the present disclosure.

FIG. 3 illustrates an exemplary metastable true random number generator (META TRNG), in accordance with an embodiment of the present disclosure.

FIGS. 4A-4B illustrates an exemplary representation of functions of a chain size selection logic circuit associated with the circuitry for generating four bits of randomly selected data, in accordance with an embodiment of the present disclosure.

FIGS. 5A-5B illustrates an exemplary representation of sample and hold blocks associated with the circuitry for generating random data, in accordance with an embodiment of the present disclosure.

FIGS. 6A-6G illustrates an exemplary representation of scrambling, unscrambling, and storage aspects associated with the circuitry for generating random data, in accordance with an embodiment of the present disclosure.

FIG. 7 illustrates an exemplary representation of method for generating random data, in accordance with an embodiment of the present disclosure.

### DETAILED DESCRIPTION

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

If the specification states a component or feature “may”, “can”, “could”, or “might” be included or have a characteristic, that particular component or feature is not required to be included or have the characteristic.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

Exemplary embodiments will now be described more fully hereinafter with reference to the accompanying drawings, in which exemplary embodiments are shown. These exemplary embodiments are provided only for illustrative purposes and so that this disclosure will be thorough and complete and will fully convey the scope of the invention to those of ordinary skill in the art. The invention disclosed may, however, be embodied in many different forms and should not be construed as limited to the embodiments set forth herein. Various modifications will be readily apparent to persons skilled in the art. The general principles defined herein may be applied to other embodiments and applications without departing from the spirit and scope of the invention. Moreover, all statements herein reciting embodiments of the invention, as well as specific examples thereof, are intended to encompass both structural and functional equivalents thereof. Additionally, it is intended that such equivalents include both currently known equivalents as well as equivalents developed in the future (i.e., any elements developed that perform the same function, regardless of structure). Also, the terminology and phraseology used is for the purpose of describing exemplary embodiments and should not be considered limiting. Thus, the present invention is to be accorded the widest scope encompassing numerous alternatives, modifications, and equivalents consistent with the principles and features disclosed. For purpose of clarity, details relating to technical material that is known in the technical fields related to the invention have not been described in detail so as not to unnecessarily obscure the present invention.

The use of any and all examples, or exemplary language (e.g., “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

The present disclosure generally relates to random number generators. More particularly, the present disclosure relates to a true random number generator with secure and improved entropy between generated sequence.

An aspect of the present disclosure pertains to an apparatus for generating random data. The random data can be numbers. The apparatus includes a ring oscillator, a metastable oscillator, a first circuitry, and an analogue circuitry. The ring oscillator has a ring oscillator output frequency selectable through a selectable input of the ring oscillator. The metastable oscillator has a metastable oscillator output frequency selectable through a selectable input of the metastable oscillator. The first circuitry has a ring oscillator (RO) chain size selection logic circuit. The analogue circuitry has a capacitor and a switch used for varying frequency of the ring oscillator. The switch is configured to be controlled by the selection logic circuit of the first circuitry.

In an aspect, the analogue circuitry is configured to vary the output frequency of the ring oscillator.

In an aspect, the RO chain size selection logic circuit is configured to generate random data based on the output frequency of the ring oscillator and the metastable oscillator.

In an aspect, the generated random data are encoded and scrambled before storage in a storage area.

In another embodiment, the apparatus further includes two or more ring oscillators, the XOR combined single output of the ring oscillators is configured to operate in tandem with the metastable oscillator, and the first circuitry to generate random data.

In another embodiment, the metastable oscillator further includes a plurality of multiplexers, and a plurality of inverters, the inverters being configured to define a size of the metastable oscillator.

In another embodiment, the chain size selection logic circuit is configured to control the size of the metastable oscillator.

In another embodiment, the chain size selection logic circuit comprises four output signals, which are randomly selected from a 256-bit random data type stored in a storage element.

In another embodiment, the randomly selected output of the chain selection logic is generated using a one-time programmable (OTP) memory block, and an XOR logic circuit.

In another embodiment, the four output signals of the RO chain size selection logic circuit is generated through an interaction of the XOR logic circuit on at least bytes of 256-bits of the generated random data.

In another embodiment, the at least four random data are selected using the XOR logic circuit.

In another embodiment, the apparatus further comprises a plurality of resistors connected in series with the drain of associated MOSFETS.

Another aspect of the present disclosure pertains to a method for generating random data. The method includes the steps of: selecting an output frequency of a ring oscillator, the output frequency selectable through a selectable input of the ring oscillator; selecting an output frequency of a metastable oscillator, the output frequency selectable through a selectable input of the metastable oscillator; varying the output frequency of the ring oscillator by a switch associated with an analogue circuitry; and generating random data at a communication circuit based on the output frequencies of the ring oscillator and the metastable oscillator.

In an embodiment, the switch varies the output frequency by a ring oscillator chain size selection logic circuit.

In another embodiment, the method further includes the steps of: selecting the output frequencies through respective selectable inputs of the two of more ring oscillators; varying the output frequencies of the two or more ring oscillators by the switch associated with the analogue circuitry; and generating random data by an XOR combination of output frequencies of the two or more ring oscillators.

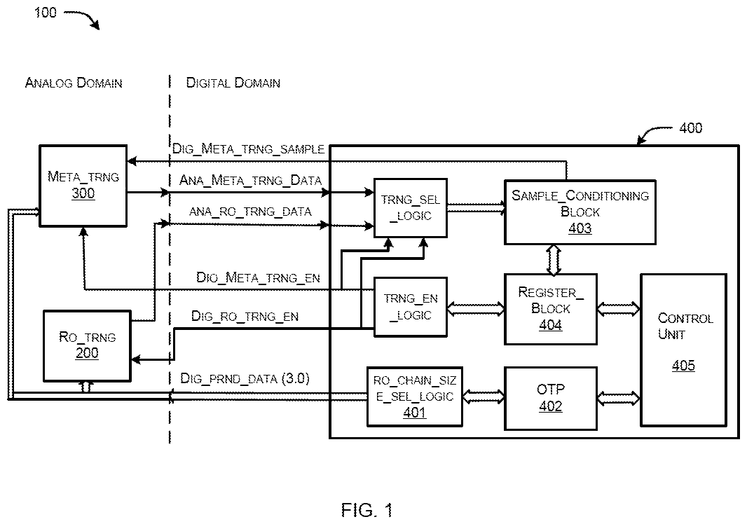

FIG. 1 illustrates an exemplary representation of an apparatus 100 for generating random data, in accordance with an embodiment of the present disclosure. The random data can be numbers in an embodiment. The apparatus 100 includes an RO TRNG, a metastable oscillator (Metastable TRNG) 300, a first circuitry (not shown), and an analogue circuitry 400. The ring oscillator (RO TRNG) 200 has a ring oscillator output frequency selectable through a selectable input of the ring oscillator 200.

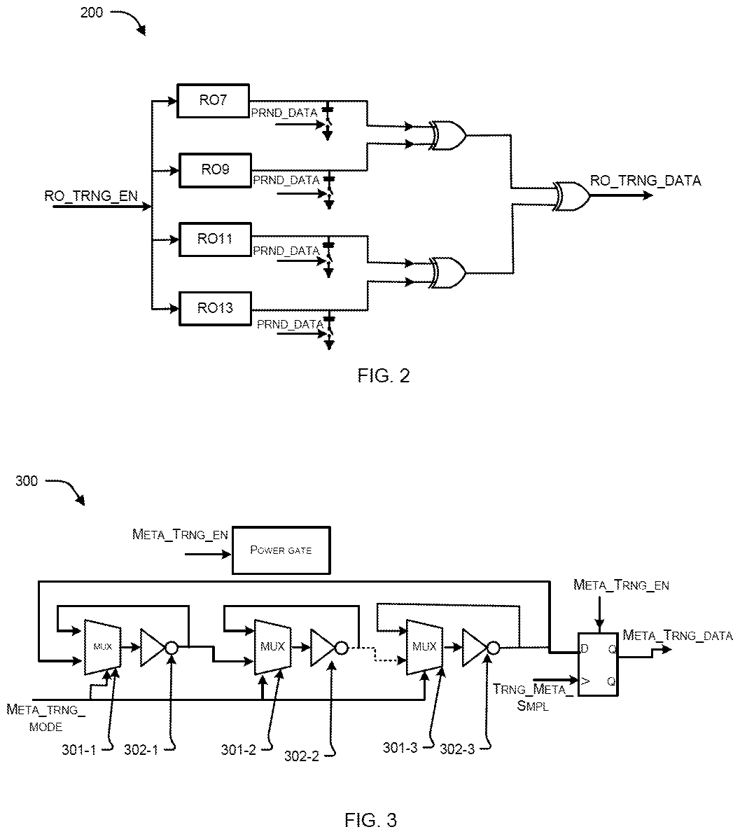

FIG. 2 illustrates an exemplary ring oscillator 200 true random number generator (RO TRNG) associated with the apparatus 100 for generating random data, in accordance with an embodiment of the present disclosure. The RO TRNG 200 typically combines the output of individual different chain RO blocks by an XOR logic. This can generate high frequency jittery pulses having very narrow pulse widths. When these pulses are sampled by the flops in digital domain (in FIG. 1), these flops can get into metastable mode which in turn provides random output post settling.

Referring again to FIG. 1, the metastable oscillator 300 has a metastable oscillator output frequency selectable through a selectable input of the metastable oscillator 300.

FIG. 3 illustrates an exemplary metastable true random number generator (META TRNG) 300, in accordance with an embodiment of the present disclosure. The basic principle of META-OSC block is the indeterministic settling of inverter output when released from metastable state. This oscillator 300 can include of odd number of META cells which can involve a 2:1 multiplexer (MUX) 301 (301-1 to 301-3; can include more in other embodiments in accordance with the desired implementation) followed by an inverter 302 (302-1 to 302-3; can include more in other embodiments in accordance with the desired implementation) as shown in FIG. 3. There can be two phases of this oscillator namely: (i) meta mode; and (ii) oscillator mode. In meta mode, input and output of inverter are shorted together so that the inverters are forced to metastable mode. In the oscillator mode the inverter inputs are connected to the output of previous output of inverter 302 in the chain which forces the inverter outputs to settle and in turn free running oscillations sustain.

Referring yet again to FIG. 1, the first circuitry has a chain size selection logic circuit 401 while the analogue circuitry 400 can include a capacitor and a switch (both not shown). The switch can be configured to be controlled by the selection logic circuit 401 of the first circuitry. The analogue circuitry 400 is capable of varying the output frequency of the ring oscillator 200. The chain size selection logic circuit 401 can be configured to generate random data based on the varying output frequencies of the ring oscillator 200 and the metastable oscillator 300. The generated random data can be encoded and scrambled before storage in a storage area. The storage area can communicatively connect with a control unit 405. The chain size selection logic circuit 401 can be configured to control the size of the metastable oscillator 300. The chain size selection logic circuit 402 can include four output signals that can be configured to generate random data based on selecting randomly from a 256-bit random data type stored in the storage area. The random selection of four bits is obtained by accessing the one-time programmable (OTP) memory block 402, and an XOR logic circuit. The four output signals of the chain size selection logic circuit 401 can be generated through an interaction of the XOR logic circuit on at least four randomly selected bytes associated with the generated random data. The at least four random data can be selected using the XOR logic circuit as is herein mentioned.

In an embodiment, the apparatus 100 further involves a plurality of resistors connected in series with the drain of associated with MOSFETS (not shown).

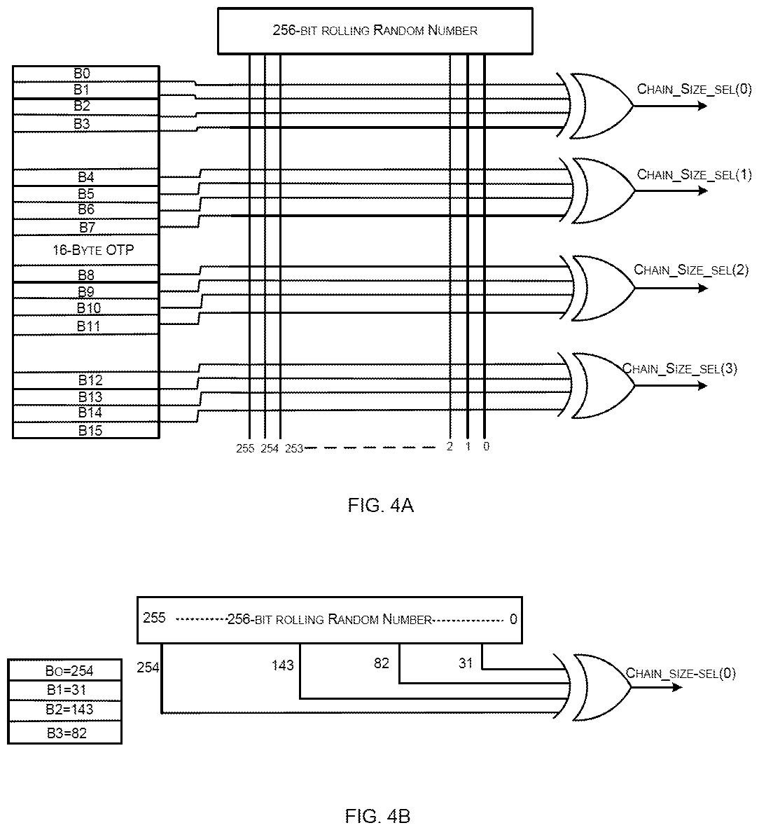

FIGS. 4A-4B illustrates an exemplary representation of functions of a chain size selection logic circuit 401 associated with the apparatus 100 for generating four bits of randomly selected data, in accordance with an embodiment of the present disclosure. Referring to FIG. 1, the 256-bit random number populated from the sample and conditioning block 403 can be read out from a register 404 and multiple bits of the random number can be selected in sets of four signals to generate an XOR output which can be one of the chain's select signals (or output frequency). The four inputs to the XOR gate can be selected based on the value in the OTP 402 as can be seen from FIG. 4B. The bits in the 256-bit random number that are given as input to the XOR gate corresponding to the output CHAIN SIZE SEL [0] are selected based on the values in the OTP bytes B0, B1, B2 and B3. The bytes in the figure are 254, 31, 143, and 82. These bits from the random number can be selected as the inputs to the XOR gate. Further, all the remaining such XOR gates outputs can be designed in the same manner in accordance with the desired implementation. The required chain select signals can thus decide the length of the Default Ring Oscillator (i.e. RO TRNG) or the Metastability based Ring Oscillator (META TRNG). From the four output bits of Chain Size selection logic, the least significant bit (LSB) is used as the signal META_TRNG_MODE for the META_TRNG oscillator. The remaining three bits are used for the Chain size selection of the META_TRNG oscillator. Whereas in the case of RO_TRNG oscillator all four bits are used for Chain size selection.

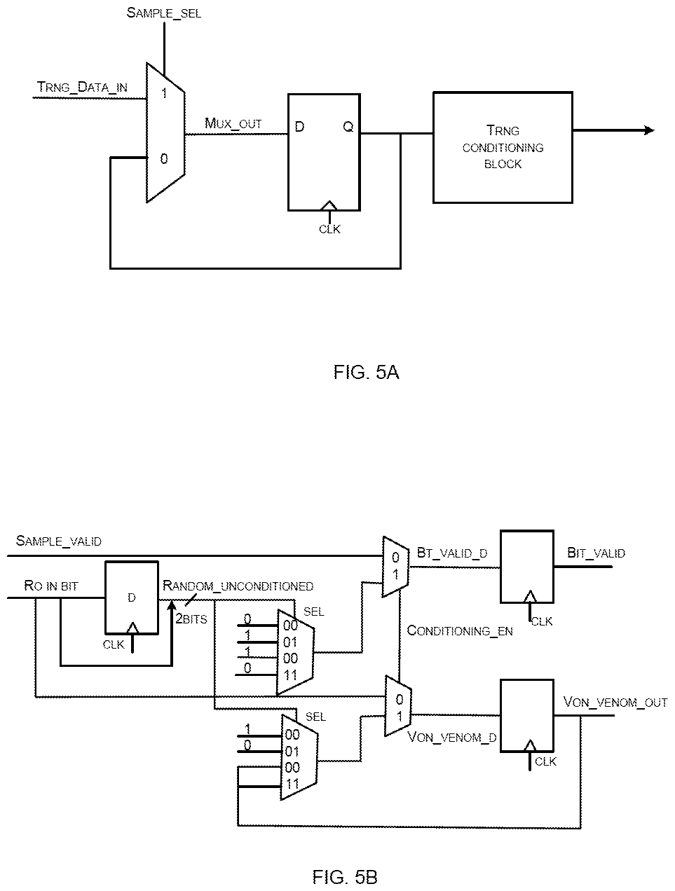

FIGS. 5A-5B illustrates an exemplary representation of sample and hold blocks associated with the circuitry for generating random data, in accordance with an embodiment of the present disclosure. The random bit string from the analogue boundary where the TRNG 100 is implemented can be sampled through a sampling flop. Von-Neumann conditioning can be used to remove the bias in the random source. FIG. 5B depicts the input/output block diagram of sample and conditioning block 403. The raw output from the TRNG can be biased, i.e. contain unequal number of 1's and 0's which also can contain a continuous string of 1's or 0's thereby impacting the entropy of random number generated. To overcome this, the output after sampling through an FF can optionally be passed through a conditioning unit. Von Neumann method of bias removal is followed which has the advantage of theoretically as well as practically having a perfect bias.

Referring again to FIG. 1, the interface with the register block 404 can be the control unit, 405 which can be made from digital logic or microprocessor or microcontroller known in the art, through which all registers can be programmed. The parameters that can be programmed that modify the behaviour of the TRNG 100 can include, without limitation, (i) INV_MODE_DUTY—indicates the duty cycle of the metastability unit inverter and sets the metastability block in the inverter mode for the duration specified by this field; (ii) INV_MODE_PERIOD—indicates the frequency at which the metastability block in the Meta TRNG changes between a metastable inverter and a part of the RO chain to generate a random bit; (iii) SAMPLE_MODE_DUTY—indicates the duty cycle for time the random bit from the Meta TRNG block is sampled before sending the conditioning block; (iv) SAMPLE_MODE_PERIOD—indicates the rate at which the random bit from Metastable oscillator is sampled and sent to the conditioning block if enabled in the register; (v) SIZE_CHANGE_PERIOD—indicates the size of the RO chain in a Meta TRNG. The entropy of the TRNG changes depending upon the values selected by this field; (vi) META_TRNG_SEL—enables the Meta TRNG signal that is driven by the RTL; (vii) RO_TRNG_SEL—enables the default TRNG signal that is driven by the RTL; (viii) CONDITIONING_EN—enables the Von-Neuman conditioning block; or (xi) RANDOM_NUM—256-bit random number captured from the output of the conditioning block.

The 256-bit random number stored in the register block 404 can be transferred to the OTP 402 when requested by the control unit 405. This number can be easily accessed and is vulnerable to security attacks from outside. The integrity of the TRNG 100 is only valid as long as the generated random number is not broken. For the purposes of this disclosure, the random number is called the private key in the text below and is used interchangeably. There are many layers at which the private key can be protected, such as at the physical level where in the material used is tamper-proof, and/or at the logical level where different functions are used to manipulate the private key from being revealed. It is envisioned that the present disclosure can also cover devices which need that extra level of security to prevent attackers from getting the private key. The protection happens at the logical level using various methods as enumerated or can be appreciated herein.

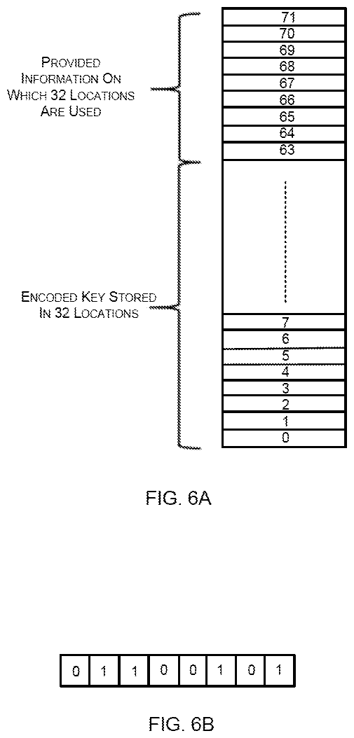

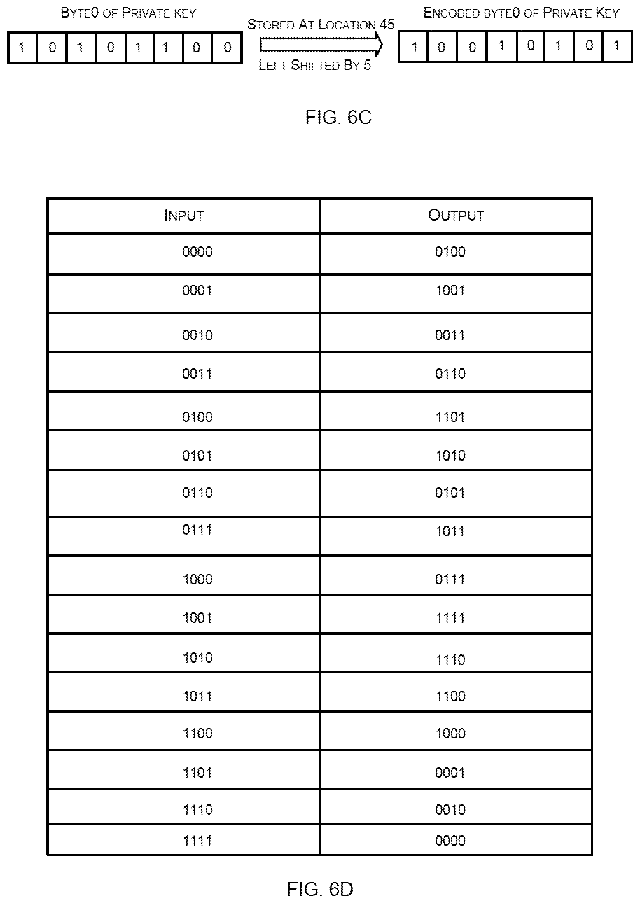

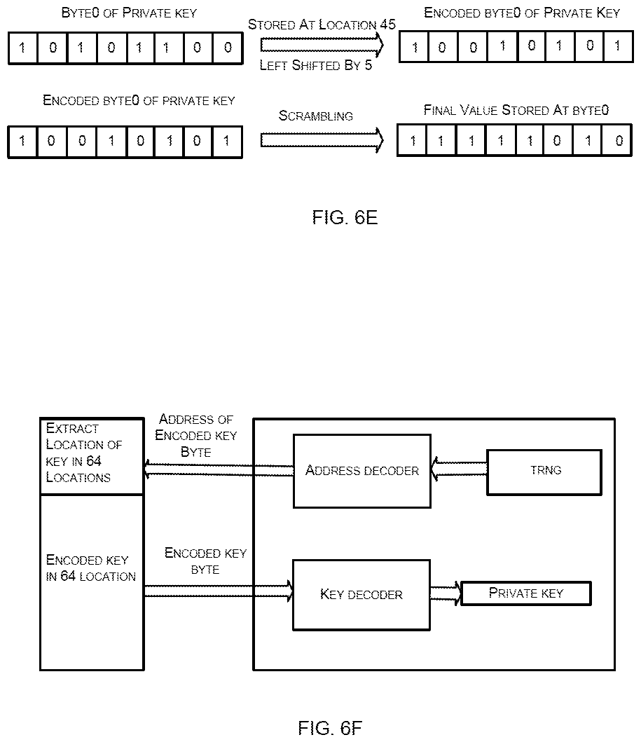

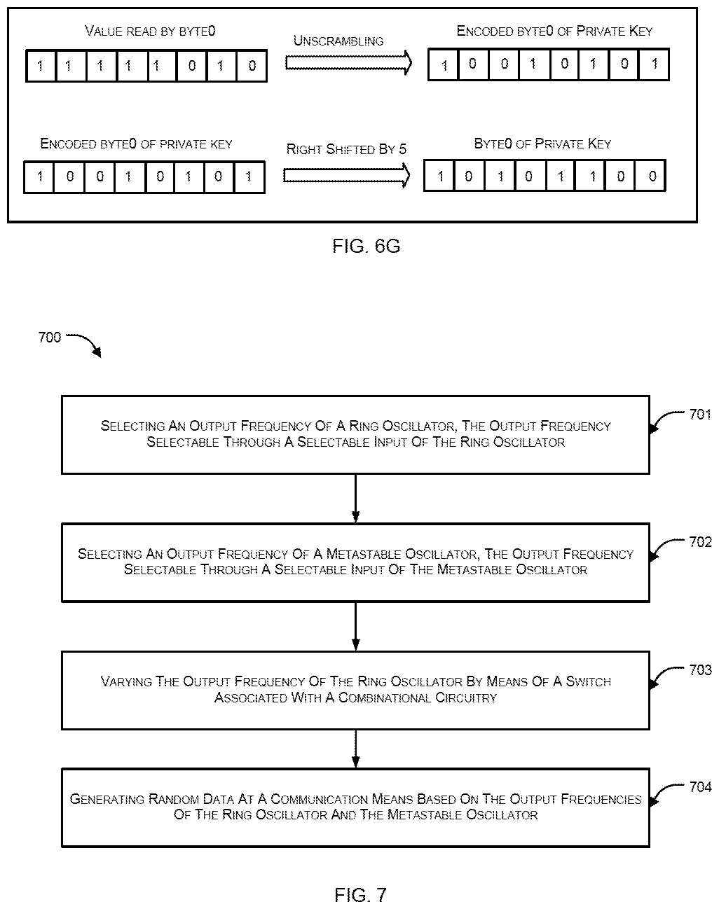

FIGS. 6A-6G illustrates an exemplary representation of scrambling, unscrambling, and storage aspects associated with the apparatus 100 for generating random data, in accordance with an embodiment of the present disclosure. The scrambling and unscrambling aspects can be associated with the control unit 405. During provisioning, the private key is not stored directly but is typically stored in an encoded manner. The 256-bit encoded value can be stored in 32 locations out of 64 locations allocated for key storage. The exact locations in which the encoded key is stored is decided during provisioning and can be modified as well. FIG. 6A depicts the way in which encoded keys are stored, and shows provisioned data containing encoded key and its locations. In the first 64 locations, 32 bytes of data are populated and the exact locations in which they are populated are according to the values in the locations 64-71. The eight bytes are one-hot encoded, and the bit location is indicative of the location in which the encoded key bytes are stored. One such location 64, is shown in the FIG. 6B (i.e. Byte denoting the exact locations at which encoded key bytes are stored). Each bit can thus correspond to a location in the 32 bytes with LSB bit denoting the LSB byte. Location 64 can correspond to the MSB bytes of the encrypted key. Thus, 62, 61, 58, and 56 locations are populated with 4 MSB bytes of the encrypted key. In similar fashion, the remaining locations until 71 are populated with 71 being the byte positions of the LSB bytes of encrypted key.

Secrecy of the private key is paramount and hence concealing the key even through memory attacks should be handled. To achieve this, instead of storing the private key itself, an encoded key is provisioned. The encoding is achieved in a two-step method. In the first step the private key is left shifted by the number of bits denoted by the location at which the private key byte is to be stored. For example, if the location of the byte stored is stored at 45(00101101). The LSB 3 bits are 101 which is 5. The private key is left shifted by 5. FIG. 6C shows a first level of encoding by a circular left shift operation. The 2nd step in which data is encoded is the scrambling step. Scrambling is performed based on the LUT mentioned herein.

FIG. 6D shows a scrambling function based on a polynomial function x³+x²+1. Here, each encoded byte from the 1st step can be scrambled nibble wise. FIG. 6E shows final encoded value after scrambling while FIG. 6F shows a block diagram that depicts key retrieval process. Whenever there is a requirement of the use of private key, a 256-bit register is populated with decoded private key. Firstly, the key can be retrieved randomly from the non-volatile memory before decoding is performed. The location bytes can be retrieved to know the exact locations where the encoded key is present. Once all the encoded bytes are loaded into a 256-bit register, the bytes can be unscrambled using the same polynomial used for scrambling. And the final step is to do a right shift of the unscrambled key to retrieve the actual private key as shown in the FIG. 6G which shows the decoding of the retrieved key.

The random order of key retrieval from the storage can thus be realized. The order in which the private key is retrieved from the storage is randomized which creates almost 2³² possibilities for the correct private key. The exact order can be known only to the block reading the private to form the entire 256-bit key. Snooping internally will thus render futile with this mechanism.

In an embodiment, fragmenting the 256-bit private key into 32 chunks of 8-bits is only one of the possible configurations. The 256-bit key can be configured to be fragmented into multiple combinations. It can be 64×4, 32×8, 16×16, 8×32 etc depending on the storage size and configuration capabilities.

FIG. 7 illustrates an exemplary representation of method for generating random data, in accordance with an embodiment of the present disclosure. The method can be performed using aspects the apparatus 100. At 701, an output frequency of a ring oscillator (e.g., ring oscillator 200) can be selected, the output frequency selectable through a selectable input of the ring oscillator. At 702, an output frequency of a metastable oscillator (e.g., metastable oscillator 300) can be selected, this output frequency also selectable through a selectable input of the metastable oscillator. At 703, the output frequency of the ring oscillator by a switch associated with an analogue circuitry can be varied. At 704, random data at a communication circuit (associated with a control unit/processor such as 405 from FIG. 1) can be generated based on the output frequencies of the ring oscillator and the metastable oscillator.

In an embodiment, the switch varies the output frequency by a ring oscillator chain size selection logic circuit.

In an embodiment, the method further comprises: selecting respective output frequencies of respective two or more ring oscillators, the output frequencies selectable through respective selectable inputs of the two of more ring oscillators; varying the output frequencies of the two or more ring oscillators by the switch associated with the analogue circuitry; and generating random data at the communication circuit based on the output frequencies of the two or more ring oscillators.

In an embodiment, the metastable oscillator (like the same in apparatus 100) further comprises a plurality of multiplexers, and a plurality of inverters, the inverters being configured to define a size of the metastable oscillator.

In an embodiment, the chain size selection logic circuit (like the same in apparatus 100) is configured to control the size of the metastable oscillator.

Thus, in an aspect, an apparatus 100 for generating random data is provided. The circuitry can have two independent oscillators via Ring Oscillator (RO-OSC) and Metastable Oscillator (META-OSC) which are selectable through respective enable signals. The two TRNG bit streams generated for RO-OSC and META-OSC are used either independently OR in combined manner to achieve higher entropy number.

In an embodiment, the RO-OSC circuitry can include multiple ring oscillator chains of different chain lengths with all outputs logically combined to provide a single output, where the logic used is an XOR gate. Frequency of all the ring oscillators can be varied by dynamically varying the logical effort of the inverter chain by adding capacitive load.

In an embodiment, the META_TRNG can include multiple META-OSC chains each having independent sampling stage. The oscillator chains are selected by LFSR outputs which are uncorrelated to the META mode select signal.

In an embodiment, the selection can be implemented through power ON-OFF of each stage which adds to the supply settling random noise.

In an embodiment, use of resistor in series with the drain of MOSFETS in meta inverter structure can reduce the power consumption which also adds to the thermal noise component.

In an embodiment, the method—feedback from the digital section 400 can provide a mechanism to generate random numbers with least correlation, thereby increasing the entropy of the entire TRNG system. The feedback is achieved by generating 4 random bits using 4 exclusive polynomials whose input is the 256-bit value in the shift register.

In an exemplary embodiment, the random number generate through the proposed system can have a high entropy (>0.97), which passes the NIST criteria.

In an embodiment, configuration modes can include sampling frequency, meta mode selection.

In an embodiment, the complete method/system for provisioning of private key can be central to Type-C Authentication or any of the authentication mechanisms as a TRNG with high entropy is central to any authentication mechanism.

In an embodiment, this present disclosure can be used for OTP or MTP flash technologies.

It should be apparent to those skilled in the art that many more modifications besides those already described are possible without departing from the inventive concepts herein. The inventive patent matter, therefore, is not to be restricted except in the spirit of the appended claims. Moreover, in interpreting both the specification and the claims, all terms should be interpreted in the broadest possible manner consistent with the context. In particular, the terms “includes” and “including” should be interpreted as referring to elements, components, or steps in a non-exclusive manner, indicating that the referenced elements, components, or steps may be present, or utilized, or combined with other elements, components, or steps that are not expressly referenced. Where the specification claims refer to at least one of something selected from the group consisting of A, B, C . . . and N, the text should be interpreted as requiring only one element from the group, not A plus N, or B plus N, etc. The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practised with modification within the spirit and scope of the appended claims.

While the foregoing describes various embodiments of the invention, other and further embodiments of the invention may be devised without departing from the basic scope thereof. The scope of the invention is determined by the claims that follow. The invention is not limited to the described embodiments, versions or examples, which are included to enable a person having ordinary skill in the art to make and use the invention when combined with information and knowledge available to the person having ordinary skill in the art.

### ADVANTAGES OF THE INVENTION

The present invention provides a true random number generator with secure and improved entropy between generated sequence.

The present invention provides a simple and cost effective true random number generator with secure and improved entropy between generated sequence, thereby producing random sequence of numbers with a high entropy.

The present invention provides a reliable and efficient true random number generator with secure and improved entropy between generated sequence, thereby producing random sequence of numbers with a high entropy.

The present invention provides a robust true random number generator with secure and improved entropy between generated sequence, thereby producing random sequence of numbers with a high entropy.

We claim:

1. An apparatus for generating random data, the apparatus comprising:
at least one ring oscillator (RO) having a ring oscillator output frequency selectable through a selectable input of the ring oscillator;
a metastable oscillator having a metastable oscillator output frequency selectable through a selectable input of the metastable oscillator;
a first circuitry having a chain size selection logic circuit; and
an analogue circuitry having a capacitor and a switch, the switch configured to be controlled by the selection logic circuit of the first circuitry,
wherein the analogue circuitry is configured to vary the ring oscillator output frequency of the at least one ring oscillator,
wherein the chain size selection logic circuit is configured to generate random data based on the ring oscillator output frequency and the metastable oscillator output frequency, and
wherein the generated random data is encoded and scrambled before storage in a storage area.

2. The apparatus as claimed in claim 1, wherein the at least one RO is two or more ring oscillators, and wherein a single output of XOR combined outputs of the two or more ring oscillators is configured to operate in tandem with the metastable oscillator and the first circuitry to generate random data.

3. The apparatus as claimed in claim 1, wherein the metastable oscillator comprises a plurality of multiplexers, and a plurality of inverters, the plurality of inverters configured to define a size of the metastable oscillator.

4. The apparatus as claimed in claim 3, wherein the apparatus further comprises a plurality of resistors connected in series with the drain of associated Metal Oxide Silicon Field Effect Transistors (MOSFETS).

5. The apparatus as claimed in claim 1, wherein the chain size selection logic circuit is configured to control the size of the metastable oscillator.

6. The apparatus as claimed in claim 5, wherein the chain size selection logic circuit comprises four outputs, which are randomly selected from a 256-bit random data type stored in a storage element, and wherein the randomly selected output of the chain selection logic circuit is generated using a one-time programmable (OTP) memory block and an XOR logic circuit.

7. The apparatus as claimed in claim 6, wherein the four output signals of the chain size selection logic circuit is generated through an interaction of the XOR logic circuit on at least bytes of 256-bits of the generated random data.

8. A method for generating random data, the method comprising:
selecting a ring oscillator output frequency through a selectable input of at least one ring oscillator;
selecting a metastable oscillator output frequency of a metastable oscillator, the metastable oscillator output frequency selectable through a selectable input of the metastable oscillator;
varying the output frequency of the at least one ring oscillator by a switch associated with an analogue circuitry; and
generating random data at a communication circuit based on the output frequencies of the at least one ring oscillator and the metastable oscillator,
wherein the switch varies the output frequency by circuit of a ring oscillator chain size selection logic circuit.

9. The method as claimed in claim 8, wherein the method comprises:
selecting the ring oscillator and the metastable oscillator output frequencies through respective selectable inputs of two of more of the at least one ring oscillator; and
varying the ring oscillator output frequencies of the two or more of the at least one ring oscillator by the switch associated with the analogue circuitry,
generating random data by an XOR combination of the ring oscillator output frequencies of the two or more ring oscillators.
